(19) United States
(12) Patent Application Publication
(10) Pub. No.: US 2026/0370015 A1
(43) Pub. Date: Nov. 19, 2026

(54) METHOD OF ELECTRICALLY POWERING A MOBILE COMPRESSOR

(71) Applicant: ATLAS COPCO AIRPOWER, NAAMLOZE VENNOOTSCHAP, Wilrijk (BE)

(72) Inventors: Stefan VELGHE, Wilrijk (BE); Ivo DANIËLS, Wilrijk (BE)

(73) Assignee: ATLAS COPCO AIRPOWER, NAAMLOZE VENNOOTSCHAP, Wilrijk (BE)

(21) Appl. No.: 19/477,425

(22) PCT Filed: Apr. 12, 2024
(86) PCT No.: PCT/IB2024/053585

§ 371 Date: Oct. 21, 2025

(30) Foreign Application Priority Data
Apr. 28, 2023 (BE) BE2023/5340

(51) Int. Cl. H02J 7/50; F04C 18/16; H02J 7/60; H02J 7/80

(52) U.S. Cl. CPC H02J 7/50; F04C 18/16; H02J 7/60; H02J 7/80

(57) ABSTRACT

An electrically powered mobile compressor including an electric motor for driving a compressor element, including an electrical connection for an electricity grid and connected to an electrical distribution device, further including an on-board charger, configured to provide electrical power thereto from the electricity grid, a battery management system for supporting power exchange between the distribution device and an assembly of one or more rechargeable batteries, a controller for measuring an electric consumer current to the electric motor, and determining a maximum charging current for the rechargeable batteries. The controller is further configured to control the on-board charger such that an electrical power is provided from the electricity grid corresponding to the sum of the consumer current and the maximum charging current.

### TECHNICAL FIELD

The present invention relates to an electrically powered compressor and to a method for controlling such an electrically powered compressor.

### STATE OF THE ART

A compressor is a machine, designed to produce compressed gases, such as compressed air. The compressed gas at a certain working pressure is then used in a range of applications, such as driving other machines such as pneumatic jackhammers and drills.

Such jackhammers and drills are usually used in locations where no permanent compressed air network is present, such as a construction site. Typically, a mobile compressor is used at these locations. The term “mobile” is therefore understood to mean that such a compressor is movable, with or without the use of transport means and/or hoisting means. In other words, a mobile compressor is a compressor that is not designed to be used stationary in a fixed location.

Mobile compressors can be driven by a diesel engine such that they can operate independently. However, as they emit combustion gases and are noisy, there is a tendency to replace these diesel engines with an electric motor. An electricity grid must then be present to power this electric motor.

Such an electrically powered mobile compressor is disclosed in BE1024040A1. The mobile compressor is equipped with a control unit to limit the maximum electrical current consumed to an adjustable maximum value. This prevents the electricity grid to which the mobile compressor is connected from being overloaded.

As further disclosed in BE1024040A1, the energy supply from the electricity grid can be further supplemented with a set of batteries. When the mobile electrically powered compressor is not active but connected to the electricity grid, the batteries can be charged. When the mobile electrically powered compressor is operational, the electric mobile compressor can draw electrical power from the electricity grid. If the grid were to fail, work can continue using power that can be drawn from the charged batteries.

A disadvantage of this disclosed electrically powered mobile compressor and associated method for controlling it is that it cannot be guaranteed at all times that electrical power is available.

It is therefore an objective of the present invention to provide a device and method that overcomes one or more of the described disadvantages of state of the art solutions. More specifically, it is an object of the present invention to provide a device and method that leads to greater autonomy of an electrically powered mobile compressor.

### SUMMARY OF THE INVENTION

According to the present invention, the above-identified objective is achieved by providing, according to a first aspect of the invention, a computer-implemented method according to claim 1 for driving an electrically powered mobile compressor comprising a compressor element driven by an electric motor for supplying a compressed gas under a predefined pressure, the electric motor connected to an electrical distribution device for providing an electrical consumer current, the distribution device further comprising:
an on-board charger, configured to provide electrical power to the electrical distribution device from an electricity grid; and
a battery management system, configured to support power exchange between the distribution device and an assembly of one or more rechargeable batteries;
   the method comprising the steps of:
measuring the electrical consumer current to the electric motor when active; and
determining a maximum charging current for the assembly of the one or more rechargeable batteries using the battery management system;
   wherein the on-board charger is controlled such that electrical power is provided from the electricity grid corresponding to the sum of the consumer current and the maximum charging current.

The electrically powered mobile compressor is configured to provide compressed air at a location where generally no compressed air network is present. On the other hand, an electricity grid is present to power the compressor. This electricity grid is, for example, a low-voltage grid at a certain voltage, such as 400V, which is common in Europe, or 480V, which is common in the United States of America. It should therefore be understood that the value of the voltage to which the mobile compressor can be connected is not limiting, but can be adapted to the region where the compressor will be used.

The compressor is provided with an electric motor to drive a compressor element. For example, the compressor element is a screw when the compressor is of the screw compressor type. Here too, it is further understood that the type of compressor element is not limiting and that other compressor elements can be used to supply the compressed gas at a predefined pressure. The value of this pressure further depends on the intended applications and can also be adjustable.

Furthermore, a mechanical coupling may be present between the electric motor and the driven compressor element, such as, for example, a gearbox. In other words, the drive of the compressor element does not have to be directly driven by the electric motor, but a mechanical coupling between them can also be provided. This will convert the speed of the electric motor into a speed, suitable for the compressor element.

Moreover, the type of electric motor is also not limiting to the disclosed invention. This can be a three-phase asynchronous electric motor, as well as a three-phase permanent magnet synchronous motor. In these cases there will be a frequency converter between the electrical distribution system and the motor. This frequency converter, also called a frequency controller, inverter, or variable speed drive, VSD, will then convert a direct voltage from the electrical distribution device to an alternating voltage with a certain frequency, suitable for the three-phase electric motor. Furthermore, both the frequency and the alternating voltage can change in order to provide a certain torque to the compressor element, depending on the required pressure of the compressed gas.

Alternatively, the electric motor can be of the direct current motor type. The direct current motor can then be directly connected to the electrical distribution device, but generally, a DC/DC converter will be present between the electrical distribution device and the DC motor to be able to apply a terminal voltage, suitable therefor.

In addition, also several electric motors may be present, each of which individ-ually drives a compressor element. A frequency controller can then be provided for each electric motor. Another possible configuration is that a single electric motor drives two or more compressor elements. When reference is made to a current for the electric motor, this also refers to the total electric current required to power the one or more motors.

The current that then flows between the electrical distribution device and the electric motor is further referred to as the electrical consumer current, or consumer current for short. Further note that this consumer current is also the current, required to drive the compressor element and thus provide compressed gas when the compressor is operational.

The electrical distribution device is a voltage rail, also called a busbar, to distribute electricity between the various connected devices. A first device is the electric motor, just discussed. The consumer current then flows from the electrical distribution device to the electric motor.

A second device, connected to the electrical distribution system, is an on-board charger. The on-board charger is configured to convert electrical power from the electricity grid to a suitable value and make it available to the electrical distribution system. Usually, an alternating current from the electricity grid will be converted into a direct current. In this case, an electric current will flow from the electricity grid through the on-board charger to the electrical distribution device to make this electrical power available to the various electrical consumers connected thereto.

Another device, connected to the electrical distribution system, is a battery management system. The battery management system is configured to support a power exchange between the distribution device and an assembly of one or more rechargeable batteries by monitoring the state of charge of this assembly. To support this, the current, voltage and temperature of one or more batteries are measured and data is exchanged with a controller on this basis. The controller then calculates a set point for the on-board charger and sends the result to the on-board charger. This allows the power exchange to take place in an optimal manner. The battery management system will also comprise a safety function to protect the batteries by not discharging them too deeply. Discharging takes place, for example, when another electrical consumer, such as the electric motor to drive the compressor element, connected to the electrical distribution device, consumes electrical power when there is no electricity grid available or the electricity grid is insufficient.

In other words, the battery management system is a system as known in the state of the art. It will therefore ensure that the batteries are kept in a safe and reliable condition. This is done, among other things, by monitoring the state of charge and ensuring that the batteries are not discharged too deeply, as will be explained further.

The connected set of rechargeable batteries is further characterized by a maximum charging current. This is the maximum value of current with which the batteries can be charged in a safe and efficient manner. As will be explained further, this value depends on the state of charge of the set of batteries. In principle, however, this will be regarded as a fixed value.

The method further comprises the step of measuring the electrical consumer current, discussed above. This measurement is done, for example, on the electric motor, or via a current measurement on the electrical distribution device using a shunt or other measuring device, suitable for determining the current. Furthermore, note that, in case the electric motor is of the asynchronous three-phase type, this electric alternating current can also be measured. A conversion will then take place to a corresponding direct current, taking into account conversion losses of the frequency converter. In other words, it should be understood that a value of direct current is measured, directly or indirectly, which is characteristic of powering the electric motor which in turn drives the compressor element.

A second step in the method is to determine the maximum charging current of the rechargeable batteries, as already explained above. This is determined using the battery management system.

Furthermore, according to a new and innovative concept, the on-board charger will be further controlled such that electrical power is provided from the electricity grid corresponding to the sum of the consumer current and the maximum charging current.

In other words, not only the consumer power is provided to energize the electric motor and thus power it when an electricity grid is present, but also an additional power is provided to be able to charge the set of batteries, simultaneously with the compressor being operational. In other words, the batteries can be charged simultaneously while keeping the compressor operational.

An on-board charger as known in the state of the art is configured to charge the batteries via the battery management system when other connected consumers, such as an electric motor, are not active. In other words, in the state of the art, either an electric motor will be powered by the set of batteries, or the batteries will be charged by a connected electricity grid. Hence, either an electrical power flow from the batteries to the electric motor, or an electrical power flow from the electricity grid to the batteries, is provided. A final possibility is that a direct power flow from the electricity grid to the electric motor is present. According to the disclosed invention, a power transfer is therefore achieved from the electricity grid to both the electric motor and to the set of one or more rechargeable batteries.

A first advantage of controlling the on-board charger in such a way is that the autonomy of the mobile compressor can be increased. Being able to charge the batteries while the compressor is operational ensures that they remain in a charged state, or at least can be recharged. If the electricity grid were to fail, it is possible to effort-lessly switch to the batteries to provide the electric motor with electrical power. It is then possible to identify the cause of the electricity grid failure, without having to ab-ruptly stop the work to be carried out with the mobile compressor.

Another advantage is that, when starting work carried out using the compressor, it is not necessary to make a choice between immediately starting the work, on the one hand, and charging the batteries if they are in a discharged or partially discharged state, on the other hand. The work can therefore be started immediately, with the on-board charger ensuring that the batteries are charged, if necessary.

A third advantage is that the electricity grid can be used optimally in this way, when present, because more power can be withdrawn from the grid than is necessary for the operation of the compressor. Once again, this allows to anticipate a possible failure of the electricity grid and to charge the batteries in the meantime.

According to an embodiment, an additional connection can be provided to the electrical distribution device for an electrical consumer, different from the electric motor and the battery management system. This connection is, for example, a socket to which an electrical appliance can be connected. The electrical current that is consumed by this device, is referred to as the electrical demand current, or simply demand current.

The method will then further comprise the step of measuring this demand current, wherein the on-board charger is then further controlled such that the electrical power from the electricity grid corresponds to the sum of the consumer current for the electric motor, the charging current for charging the batteries, and the aforementioned demand current for the electrical appliance.

This will again guarantee that the batteries can be charged when they are discharged or partially discharged, while the electrical appliance can be provided with the necessary power.

According to a preferred embodiment, the method further comprises the steps of:
determining the state of charge of the assembly of the one or more rechargeable batteries using the battery management system; and
adjusting the maximum charging current when the state of charge exceeds a predefined value.

In other words, the charge status of the rechargeable batteries will be continu-ously monitored and the maximum charging current will be determined on this basis. Adjusting the maximum charging current can then be done in two ways.

When the state of charge exceeds a certain value in an upward direction, for example more than 90% charged, the charging current will be limited such that the batteries are charged with a lower charging current. This prevents the batteries from being damaged by too high a charging current. When the batteries are fully charged, the charging current can be reduced to zero.

On the other hand, it may also be that the state of charge exceeds a certain value in a downward direction. Using the same example, the state of charge can drop below 90%. The charging current will then be adjusted in a positive sense, namely that it will assume a higher value, and the batteries can therefore be charged faster.

The electrical power withdrawn from or allowed to the electricity grid by the on-board charger will also adjust, based on changes in the maximum charging current. This will prevent the voltage on the electrical distribution device from rising too high and/or a surplus of electrical power being present on the electrical distribution device, which could negatively affect the proper functioning of the connected electrical appli-ances.

According to a preferred embodiment, the method further comprises the step of controlling the on-board charger by the battery management system to charge one or more rechargeable batteries of the assembly of the one or more rechargeable batteries, based on a respective state of charge. More specifically, the on-board charger will be controlled by a controller, based on data from the battery management system as explained above.

In other words, the electrical power that is made available on the electrical distribution device by controlling the on-board charger will then be used by the battery management system to charge the batteries. This is done based on the charge status of the respective batteries and is monitored and controlled by the battery management system.

According to an embodiment of the invention, the method further comprises the step of, when the electrical power corresponding to the sum of the consumer current and the maximum charging current, and the demand current, if present, exceeds a maximum power of the electricity grid, limiting the predefined pressure such that the electrical consumer current is limited. As a result, the batteries will be charged less quickly in order to supply the compressor with the required power.

When the electrical power, available from the electricity grid, is insufficient to both power the electric motor and charge the batteries, this can be anticipated by low-ering the pressure. This will also reduce the power, required by the electric motor, and therefore also the consumer current. This will also reduce the total electrical power required, while ensuring that the batteries can be charged quickly and efficiently.

According to a second aspect of the invention, there is disclosed an electrically powered mobile compressor, the electrically powered mobile compressor comprising an electric motor for driving a compressor element for providing a compressed gas under a predefined pressure, the compressor further comprising an electric connection for an electricity grid, the electric motor connected to an electrical distribution device, the electrical distribution device further comprising:
an on-board charger, configured to provide electrical power to the electrical distribution device from the electricity grid; and
a battery management system, configured to support power exchange between the distribution device and an assembly of one or more rechargeable batteries;
a controller, configured to measure a consumer electric current to the electric motor when active, and to determine a maximum charging current for the assembly of the one or more rechargeable batteries;
   wherein the controller is further configured to control the on-board charger such that an electrical power is provided from the electricity grid corresponding to the sum of the consumer current and the maximum charging current.

Furthermore, the compressor may comprise a frequency controller between the electric motor and the electrical distribution device, configured to convert a direct voltage from the electrical distribution device into an alternating voltage with a certain frequency, suitable for the electric motor. Note that this corresponds to the method of the invention already discussed.

An additional connection to the electrical distribution device for an electrical consumer may also be present, wherein the controller is then further configured to measure an electrical demand current to the electrical consumer, and to control the on-board charger such that electrical power is supplied from the electricity grid, corresponding to the sum of the consumer current, the charging current, and the demand current.

Furthermore, according to a preferred embodiment, the compressor comprises one or more rechargeable batteries.

Furthermore, the controller may be configured to determine the state of charge of the assembly of the one or more rechargeable batteries using the battery management system, when present, and to adjust the maximum charging current when the state of charge exceeds a predefined value. Note that the same approach is followed as the method described above.

The controller is further configured to control the on-board charger, based on data exchanged with the battery management system for charging one or more rechargeable batteries of the assembly of the one or more rechargeable batteries, when present, based on a respective state of charge.

According to a third aspect of the invention, there is disclosed a controller, configured to perform the method according to the first aspect.

According to a fourth aspect, there is disclosed a data processing system comprising a processing unit, configured to perform the method according to the first aspect.

According to a fifth aspect, there is disclosed a computer program product, containing computer-executable instructions to perform the method according to the first aspect when this program is executed on a computer.

According to a sixth aspect, there is disclosed a computer readable storage medium, containing the computer program product according to the fifth aspect.

### BRIEF DESCRIPTION OF THE DRAWINGS

The invention will be further illustrated with reference to the figures, wherein

FIG. 1 schematically illustrates an electrical distribution device with an electric motor, an on-board charger, and a battery with a battery management system connected thereto; and

FIG. 2 schematically illustrates an electrical distribution device as in FIG. 2 with an electrical consumer connected thereto; and

FIG. 3 illustrates an electrically powered mobile compressor including the electrical distribution device as shown in FIG. 1 or FIG. 2; and

FIG. 4 illustrates the course of the consumer current, the maximum charging current, and a discharge current in different operating modes; and

FIG. 5 schematically illustrates different operating modes.

### DETAILED DESCRIPTION OF THE EMBODIMENTS

The present invention will be described with respect to certain embodiments and with reference to certain drawings, but the invention is not limited thereto and is determined only by the claims. The drawings described are only schematic and non-limiting. In the drawings, the size of certain elements may be exaggerated and not drawn to scale for illustrative purposes. The dimensions and relative dimensions do not necessarily correspond to actual practical embodiments of the invention.

Furthermore, the terms first, second, third and the like are used in the description and in the claims to distinguish between similar elements and not necessarily to describe a sequential or chronological order. The terms are interchangeable under appropriate circumstances and the embodiments of the invention may be practiced in sequences other than those described or illustrated herein.

In addition, the terms above, below, over, below and the like in the description and claims are used for illustrative purposes and not necessarily to describe relative positions. The terms so used are interchangeable under appropriate circumstances and the embodiments of the invention described herein may be employed in orienta-tions other than those described or illustrated herein.

Furthermore, the various embodiments, although referred to as “preferred embodiments”, are to be construed as exemplary means of carrying out the invention rather than as a limitation on the scope of the invention.

The term “comprising” used in the claims should not be construed as being limited to the means or steps set forth below; the term does not exclude other elements or steps. The term should be interpreted as specifying the presence of the mentioned features, elements, steps or components referred to, but does not exclude the presence or addition of one or more other features, elements, steps or components, or groups thereof. The scope of the expression “a device comprising means A and B” should therefore not be limited to devices consisting only of components A and B. The meaning is that with respect to the present invention only components A and B of the device are listed, and the claim is further construed to also include equivalents of these components.

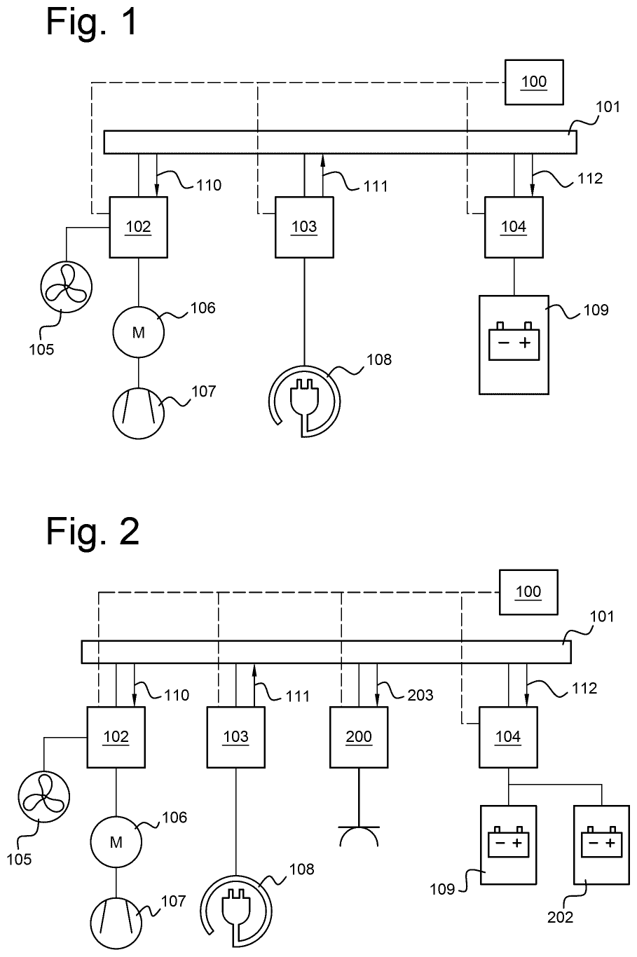

FIG. 1 schematically illustrates an electrical distribution device 101 with an electric motor 106, an on-board charger 103, and a battery management system 104 with a set of batteries 109 connected thereto. Furthermore, an electrical connection 108 to an external electricity grid, a controller 100, an inverter 102, a compressor element 107, and a fan 105 is illustrated.

In FIG. 2, the same electrical distribution device 101 as in FIG. 1 is also illustrated with an electrical converter 200 and an electrical connection 201, such as a socket, to which an electrical consumer can be connected.

The electrical distribution device 101, also called a busbar, serves as a distribution board to distribute electrical power among the consumers, such as the electric motor 106, the batteries 109 to charge them if necessary, and an electrical consumer connected to the electrical connection 200 if present. The electrical power present on the distribution device 101 is of the direct voltage type.

With reference again to FIG. 1, the inverter 102 serves to convert the direct voltage from the distribution device 101 into a voltage, suitable for the electric motor 106. The inverter 102 is, for example, a frequency converter, also called a frequency controller, inverter, or variable speed drive, VSD, when the electric motor 106 is a three-phase motor, and suitable for connection to a direct current voltage source with a value in a range of, for example, 441 to 715 V _{DC}. The inverter can also be a DC/DC converter when the electric motor 106 is a direct current motor.

The electric motor 106 then drives the compressor element 107 to provide a compressed gas, usually ambient air for a mobile compressor, at a predefined pressure or flow rate. The motor is, for example, a three-phase asynchronous motor with a power of 33 kW.

Although not illustrated, a mechanical coupling between the electric motor 106 and the compressor element 107 may also be present. This coupling is, for example, a gearbox and then ensures that the speed of the electric motor 106 is converted into a speed, suitable for driving the compressor element 107.

Furthermore, the compressor can be provided with a fan 105, also connected to the inverter, as a cooling system for the electric motor 106 and/or the compressor element 107. The fan 105 is, for example, powered with a voltage of 28 V. Note that other cooling systems can also be provided. It is further understood that the current to power the electric motor, as discussed further, also encompasses a current to drive the fan 105, or an alternative cooling system.

Alternatively, the cooling system can comprise a fan that is connected to the distribution device 101 via its own inverter. In that case, an additional demand current will be present, that must be taken into account. This own inverter can be the inverter 200, wherein the fan is connected to the available socket 201 and the fan determines the demand current.

The on-board charger 103 is a device that converts power from an external electricity grid via the electrical connection 108 into a direct voltage, suitable for the electrical distribution device 101. The controller 100 will determine the power that is to be withdrawn from the electricity grid and therefore what the current is that will flow to the electrical distribution device 101, and for this purpose, it will control the on-board charger 103. This power will be determined by the state of charge of the rechargeable batteries 109, the required power for the electric motor 106, and the current for a consumer when connected to the additional inverter 200 and connection 201.

Furthermore, the on-board charger 103 itself is also characterized by a maximum power that it can withdraw from the electricity grid. For example, the on-board charger 103 has a capacity of 22 KW, where the connection 108 to the grid is a socket with a nominal current of 63 A. This means that a maximum of 22 KW of electrical power can be made available on the electrical distribution device 101. To expand the capacity, more than one on-board charger can be provided, each with its own connection. The controller 100 will then be configured to control multiple on-board chargers.

With reference again to FIG. 1, the current, withdrawn from the electricity grid, is illustrated by reference numeral 111. The current flowing to the electric motor is illustrated by reference numeral 110, and the charging current to charge the batteries by reference numeral 112. These currents 110-112 will then be in balance. With reference to FIG. 2, there may be an additional current to a consumer illustrated by reference numeral 203. The additional connection 201 is, for example, a socket with a nominal current of 32 A.

In addition, there may also be several sets of batteries present, such as in this example the set of batteries 202 in addition to the set already present 109. A set of batteries can then, for example, have a voltage range between 440 V and 715 V, which is in accordance with the inverter 102, such that both devices can be simultaneously connected to the electrical distribution device 101 in a safe condition.

The controller 100 is configured to communicate with the on-board charger 103. Furthermore, the controller 100 communicates with the inverter 102, and the battery management system 104. If no inverter 102 is present, i.e. in the case that the electric motor 106 is directly connected to the electrical distribution device 101, reference numeral 102 illustrates a measuring unit for determining what current 110 the electric motor 106 needs to drive the compressor element 107. It is therefore important that the controller 100 can determine what the electrical consumer current 110 is for the electric motor 106, when active.

With the aid of the battery management system 104, the controller will also determine the maximum charging current 112 to charge the assembly of the batteries 109. For example, a maximum charging current can be 132 A. The battery management system 104 monitors the charging status of the batteries 109 and communicates to the controller 100 what the maximum charging current 112 is. The controller 100 will then control the on-board charger on the basis of the sum of consumer current 110 and the maximum charging current 112 such that this sum corresponds to the current 111 that is withdrawn from the grid. With the examples mentioned above, the maximum current that can be withdrawn from the grid is 205.9 A. Please note, however, that, due to the limitation of the on-board charger power of 22 KW, the current will be limited to 49.3 A. It is then possible to opt to connect several on-board chargers in parallel to provide this maximum current of 205.9 A.

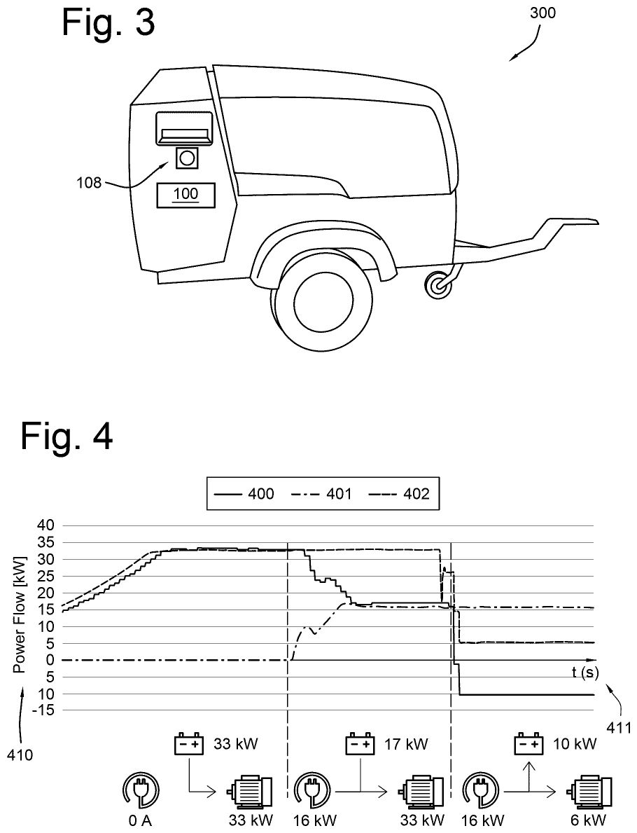

The arrangement illustrated in FIG. 1 and FIG. 2 is then integrated into a mobile compressor 300 as illustrated in FIG. 3. This then has a connection 108, for example a socket with a nominal current of 63 A, to connect the compressor 300 to an external electricity grid. Furthermore, a user interface may be available to operate the controller 100 and/or read the status of the various components. A first example is the state of charge of the set of batteries 109, 202, as well as the remaining time required to fully charge the batteries 109, 202. Other information that can be read is the pressure of the compressed gas, the speed of the compressor element 107, and the total amount of time the compressor 300 has been active.

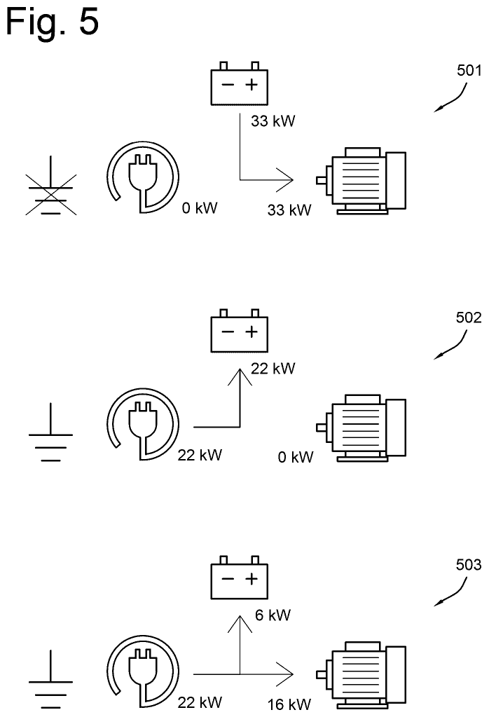

With reference to FIG. 5, the compressor 300 can also operate in different operating modes 501-503. A first operating mode 501 is the one in which the compressor operates completely autonomously, in other words in which the electric motor with-draws the total electrical power, in this example 33 KW, from the set of batteries 109, 202. This situation can occur when no electricity grid is available. The electrical power of 33 KW then corresponds to a maximum electrical current of 73.9 A, drawn from the electricity grid.

A second operating mode 502 is the one where the compressor 300 is not active, but where an electricity grid is available. The rechargeable batteries 109, 202 will be charged, in this example with a charging current 112 corresponding to a power of 22 kW. A charging current of a maximum of 49.3 A will then flow to the battery management system in order to charge the batteries 109, 202.

A third illustrated operating mode 503 is the one in which an electricity grid is present and the compressor 300 is also active. A power of 22 KW can then be made available from the grid, as already explained based on the power of the on-board charger 103. In this example, the electrical power for the electric motor 106 is limited to 16 KW, due to a lower consumption of compressed air from the compressor such that the batteries 109, 202 can then be charged with an electrical power of 6 KW while the compressor is operational at a partial load of 16 KW, compared to the maximum power of 33 kW.

With reference to FIG. 4, finally, an illustration is given, based on a set of graphs of the course of the power flow, illustrated on the y-axis 410 in the kW unit, over time on the x-axis in the seconds unit. Graph 400 represents the power flow to and from the batteries 109, 202, graph 401 the electrical power withdrawn from the electricity grid via connection 108, and graph 402 the power that flows to the electric motor 106 for driving the compressor element 107.

On the left side of the illustration, an operating mode is shown in which the electric motor 106 is powered entirely by power from the batteries 109, 202. This therefore corresponds to operating mode 501 as illustrated in FIG. 5. On the right side, an illustration of an operating mode is shown in which the electric motor 106 is powered and the batteries 109, 202 are charged. This corresponds to the operating mode 503 as illustrated in FIG. 5. Finally, between the left side and the right side of the illustration, a transitional operating mode is shown, in which the electric motor 106 is powered with electrical power from both the electricity grid via connection 108 and the set of batteries 109, 202. This corresponds to the operating mode 503, as illustrated in FIG. 5.

1-16. (canceled)

17. A computer-implemented method of controlling an electrically powered mobile compressor comprising a compressor element driven by an electric motor for supplying a compressed gas under a predefined pressure, the electric motor connected to an electrical distribution device for providing an electrical consumer current, the distribution device further comprising:
an on-board charger, configured to provide electrical power to the electrical distribution device from an electricity grid; and
a battery management system, configured to support power exchange between the distribution device and an assembly of one or more rechargeable batteries;
the method comprising the steps of:
measuring the electrical consumer current to the electric motor when active; and
determining a maximum charging current for the assembly of the one or more rechargeable batteries using the battery management system;
wherein the on-board charger is controlled such that electrical power is provided from the electricity grid corresponding to the sum of the consumer current and the maximum charging current.

18. The computer-implemented method according to claim 17, wherein, when the electrical distribution device further comprises a connection for an electrical consumer, the method further comprises the steps of:
measuring an electrical demand current of the electrical consumer;
and wherein the on-board charger is further controlled such that an electrical power is provided from the electricity grid corresponding to the sum of the consumer current, the charging current, and the demand current.

19. The computer-implemented method according to claim 17, further comprising the steps of:
determining the state of charge of the assembly of the one or more rechargeable batteries using the battery management system; and
adjusting the maximum charging current when the state of charge exceeds a predefined value.

20. The computer-implemented method according to claim 19, further comprising the step of:
controlling the on-board charger by the battery management system to charge one or more rechargeable batteries of the assembly of the one or more rechargeable batteries based on a respective charging state.

21. The computer-implemented method according to claim 17, wherein, when the electrical power corresponds to the sum of the consumer current and the maximum charging current, and the demand current, if present, exceeds a maximum power of the electricity grid, further comprises the step of:
limiting the predefined pressure such that the electrical consumer current is limited.

22. An electrically powered mobile compressor comprising an electric motor for driving a compressor element for providing a compressed gas under a predefined pressure and/or flow rate, the compressor further comprising an electrical connection for an electricity grid, the electric motor connected to an electrical distribution device, the electrical distribution device further comprising:
an on-board charger, configured to provide an electrical power to the electrical distribution device from the electricity grid; and
a battery management system, configured to support power exchange between the distribution device and an assembly of one or more rechargeable batteries;
a controller, configured to measure a consumer electric current to the electric motor when active, and to determine a maximum charging current for the assembly of the one or more rechargeable batteries;
wherein the controller is further configured to control the on-board charger such that an electrical power is provided from the electricity grid corresponding to the sum of the consumer current and the maximum charging current.

23. The electrically powered mobile compressor according to claim 22, further comprising a frequency controller between the electric motor and the electrical distribution device, configured to convert a direct current voltage from the electrical distribution device to an alternating voltage with a certain frequency, suitable for the electric motor.

24. The electrically powered mobile compressor according to claim 22, further comprising an inverter on the electrical distribution device for an electrical consumer, and wherein the controller is further configured to measure an electrical demand current to the electrical consumer, and to control the on-board charger such that an electrical power is provided from the electricity grid corresponding to the sum of the consumer current, the charging current, and the demand current.

25. The electrically powered mobile compressor according to claim 22, further comprising the assembly of the one or more rechargeable batteries.

26. The electrically powered mobile compressor according to claim 22, wherein the controller is further configured to determine the state of charge of the assembly of the one or more rechargeable batteries using the battery management system, and adjust the maximum charging current when the state of charge exceeds a predefined value.

27. The electrically powered mobile compressor according to claim 26, wherein the controller is further configured to control the battery management system for charging one or more rechargeable batteries of the assembly of the one or more rechargeable batteries, when present, based on a respective state of charge.

28. A controller, configured to perform the method according to claim 17.

29. A data processing system, comprising a processing unit, configured to perform the method according to claim 17.

31. A computer readable storage medium, containing a computer program product containing computer-executable instructions to perform the method according to claim 17 when executed on a computer.

31. A method of controlling an electrically powered mobile compressor comprising a compressor element driven by an electric motor for supplying a compressed gas under a predefined pressure, the electric motor connected to an electrical distribution device for providing an electrical consumer current, the distribution device further comprising:
an on-board charger, configured to provide electrical power to the electrical distribution device from an electricity grid; and
a battery management system, configured to support power exchange between the distribution device and an assembly of one or more rechargeable batteries;
the method comprising the steps of:
measuring the electrical consumer current to the electric motor when active; and
determining a maximum charging current for the assembly of the one or more rechargeable batteries using the battery management system;
wherein the on-board charger is controlled such that electrical power is provided from the electricity grid corresponding to the sum of the consumer current and the maximum charging current.
